(19) United States
(12) Patent Application Publication
(10) Pub. No.: US 2016/0181326 A1
(43) Pub. Date: Jun. 23, 2016

(54) Radiation-Emitting Apparatus and Method for Producing Same

(71) Applicant: OSRAM OLED GMBH, Regensburg (DE)

(72) Inventor: Andrew Ingle, Allershausen (DE)

(21) Appl. No.: 14/909,104

(22) PCT Filed: Sep. 5, 2014
(86) PCT No.: PCT/EP2014/068953

§ 371 Date: Jan. 30, 2016

(30) Foreign Application Priority Data
Sep. 9, 2013 (DE) 10 2013 109 822.3

(51) Int. Cl. H01L 27/32; H01L 51/56; H01L 51/52

(52) U.S. Cl. CPC H01L 27/3202; H01L 51/5246; H01L 51/56; H01L 27/3276

(57) ABSTRACT

A radiation-emitting apparatus includes a substrate and a number of optoelectronic components arranged on the substrate in rows running parallel to a preferred direction. Each optoelectronic component includes a sequence of layers suitable for generating electromagnetic radiation. The radiation-emitting apparatus also includes a cover element which is arranged on the plurality of optoelectronic components and which comprises a number of first contact elements, each of which is electrically connected to the first electrode faces of at least some of the optoelectronic components and a number of second contact elements, each of which is electrically connected to the second electrode faces of at least some of the optoelectronic components. The contact elements are in the form of strips and extend in the preferred direction.

This patent application is a national phase filing under section 371 of PCT/EP2014/068953, filed Sep. 5, 2014, which claims the priority of German patent application 10 2013 109 822.3, filed Sep. 9, 2013, each of which is incorporated herein by reference in its entirety.

### TECHNICAL FIELD

A radiation-emitting apparatus and a method for producing same are described.

### BACKGROUND

Radiation-emitting apparatuses and in particular those that comprise organic light-emitting diodes (OLEDs) are suitable as large-scale, thin lighting elements. In many applications, it is desirable for electromagnetic radiation to be emitted over the largest lighting surface possible. However, there are a number of factors that limit arbitrary scaling of the radiation-emitting apparatuses. For example, the high surface resistivity of transparent electrodes is extremely limiting.

One solution known from the prior art resides in arranging a multiplicity of separated OLED devices next to each other on a surface, wherein these devices are electrically connected together via external structures. Typically, the OLED devices comprise plug elements or frame elements by means of which they can be attached to a plate. A disadvantage of this solution is that it requires a separation into individual OLED devices and thus requires a method step that signifies a relatively high cost.

### SUMMARY

At least one embodiment provides a radiation-emitting apparatus having a large lighting surface that has a radiation intensity as homogeneous as possible. Embodiments of the invention provide a radiation-emitting apparatus that can be produced without a method step directed to the separation into individual light-emitting devices.

According to at least one embodiment of the radiation-emitting apparatus, a radiation-emitting apparatus comprises a substrate and a multiplicity of optoelectronic devices arranged on the substrate.

The fact that a layer or an element is arranged or applied “on” or “over” another layer or another element or even “between” two other layers or elements may mean here and hereinafter that the one layer or the one element is arranged in direct mechanical and/or electrical contact on the other layer or the other element. It may moreover also mean that the one layer or the one element is arranged indirectly on or over the other layer or the other element. In this case, further layers and/or elements may then be arranged between the one layer and the other layer or the one element and the other element.

The optoelectronic devices are arranged in rows that extend in parallel with a preferential direction. Each of the optoelectronic devices comprises a layer sequence that is suitable for generating electromagnetic radiation having at least one first electrode surface (that is formed, for example, as a cathode), at least one second electrode surface (that is formed, for example, as an anode) and at least one functional layer between the first electrode surface and the second electrode surface. The functional layer is suitable for generating electromagnetic radiation in a switched-on operating state. Moreover, the radiation-emitting apparatus comprises a cover element that is arranged on the multiplicity of optoelectronic devices. Therefore, the optoelectronic devices are arranged between the substrate and the cover element, wherein the substrate and/or the cover element can be formed so as to protect the optoelectronic devices from moisture and/or oxygen. The cover element comprises a cover support that preferably consists of glass or a polymer or contains one of these materials. Furthermore, an additional thin-film encapsulation can be provided between the optoelectronic devices and the cover element.

The cover element comprises a multiplicity of first contact elements that are each connected (directly or indirectly) to the first electrode surfaces (e.g., the cathodes) of at least some of the optoelectronic devices in an electrically conductive manner. The first contact elements are formed in a strip-like manner and extend along the preferential direction.

The cover element further comprises a multiplicity of second contact elements that are each connected (directly or indirectly) to the second electrode surfaces (e.g., the anodes) of at least some of the optoelectronic devices in an electrically conductive manner. The second contact elements are formed in a strip-like manner and extend along the preferential direction. Preferably, the first electrode surfaces of the optoelectronic devices are exclusively allocated a first polarity and are formed, for example, as cathodes or act as cathodes. Similarly, the second electrode surfaces of the optoelectronic devices are preferably exclusively allocated a second polarity and are formed, for example, as anodes or act as anodes.

Preferably, the first contact elements are exclusively connected to the first electrode surfaces of at least some of the optoelectronic devices in an electrically conductive manner and are not connected to a second electrode surface of an optoelectronic device. Similarly, it is preferred that the second contact elements are exclusively connected to the second electrode surfaces of at least some of the optoelectronic devices in an electrically conductive manner and are not connected to a first electrode surface of an optoelectronic device. For example, first contact elements are exclusively connected to the cathodes of at least some of the optoelectronic devices in an electrically conductive manner and are not connected to an anode of an optoelectronic device. Similarly and for example, the second contact elements are exclusively connected to the anodes of at least some of the optoelectronic devices in an electrically conductive manner and are not connected to a cathode of an optoelectronic device.

By virtue of the fact that the cover element comprises contact elements, by way of which the electrode surfaces of the optoelectronic devices are contacted, the optoelectronic devices can be left on the original manufacturing substrate (or “mother glass”) without partitioning of the manufacturing substrate and thus separation into individual devices being required. Rather, the radiation-emitting apparatus is formed as a monolithic structure, in which the original manufacturing substrate is retained in a compact manner and forms the substrate of the radiation-emitting apparatus.

Compared with apparatuses known from the prior art, no additional lead frames are required in order to conceal the edge regions of the devices. Moreover, the distances between the optoelectronic devices can be reduced compared with the prior art because the structure does not have to be severed in the regions between the devices. Severing of the manufacturing substrate, e.g., by scoring and breaking, is only required along some lines or even just one line (e.g., by laser treatment), namely at the edges of the substrate of the radiation-emitting apparatus.

The contact elements typically formed as metallic structures provide for a reduction in the voltage loss between the individual devices owing to the comparably low resistance thereof. The individual devices are not connected by external structures but by a connection between the contact elements and the electrode surfaces in the region between the devices and thus by an internal configuration.

According to at least one embodiment of the radiation-emitting apparatus, provision is made that the layer sequence of each of the optoelectronic devices comprises an organic functional layer, in particular an organic electroluminescent layer. The optoelectronic devices are thus formed as OLEDs.

The functional layers can comprise in particular an organic functional layer stack having an organic electroluminescent layer. The organic functional layer stack can comprise, e.g., a hole injection layer, a hole transport layer, an electron blocking layer, a hole blocking layer, an electron transport layer and/or an electron injection layer that are suitable for conducting holes or electrons to the organic electroluminescent layer or for blocking the respective transport, respectively. Suitable layer structures for the organic functional layer stack are known to the person skilled in the art and are therefore not explained any further at this point.

According to at least one embodiment of the radiation-emitting apparatus, provision is made that a length and/or width of each optoelectronic device is between 1 mm and 10 cm, preferably between 2 mm and 2 cm.

According to at least one embodiment of the radiation-emitting apparatus, provision is made that a length and/or width of the substrate and/or the cover element is between 10 mm and 5 m, preferably between 10 cm and 1 m.

According to at least one embodiment of the radiation-emitting apparatus, provision is made that a thickness of the substrate and/or the cover element is between 0.1 mm and 5 cm, preferably between 0.5 mm and 5 mm.

According to at least one embodiment of the radiation-emitting apparatus, provision is made that the first or second electrode surfaces are transparent. Preferably, the electrode surfaces that are arranged between the functional layers and the substrate are transparent, and so light emitted from the functional layers can be radiated through the electrode surfaces and the substrate.

The transparent electrode surfaces preferably comprise a transparent conductive oxide (TCO). Transparent conductive oxides are transparent, conductive materials, generally metal oxides, such as, for example, zinc oxide, tin oxide, cadmium oxide, titanium oxide, indium oxide or indium-tin oxide (ITO).

According to at least one embodiment of the radiation-emitting apparatus, provision is made that the substrate is transparent. In this case, a radiation exit surface of the radiation-emitting apparatus can be formed by the substrate. Preferably, the substrate consists of glass or a polymer or contains one of these materials.

According to at least one embodiment of the radiation-emitting apparatus, provision is made that each of the first contact elements is arranged in each case over one of the rows of optoelectronic devices.

According to at least one embodiment of the radiation-emitting apparatus, provision is made that each of the second contact elements is arranged in each case over a region between two adjacent rows of optoelectronic devices.

According to at least one embodiment of the radiation-emitting apparatus, provision is made that each of the first contact elements is connected in each case to first contact structures that are formed in regions between two optoelectronic devices lying next to each other (adjacent) in a row.

According to at least one embodiment of the radiation-emitting apparatus, provision is made that each of the second contact elements is connected in each case to second contact structures that are formed in regions between two optoelectronic devices lying next to each other from two adjacent rows.

According to at least one embodiment of the radiation-emitting apparatus, provision is made that at least some of the contact elements are attached to at least some of the contact structures via a conductive adhesive.

According to at least one embodiment of the radiation-emitting apparatus, provision is made that the contact elements are formed by a structured metallization on one of the major surfaces of the cover support. Preferably, the metallization is a laser-structured metallization.

According to at least one embodiment of the radiation-emitting apparatus, provision is made that the cover element protrudes beyond the substrate in the preferential direction. In the region not covered by the substrate, the contact elements of the cover element can be easily contacted from the outside. Preferably, the region of the cover element not covered by the substrate forms a contacting strip that, for example, can be inserted into a corresponding separate fitting, by way of which the radiation-emitting apparatus can be supplied with electrical energy.

A further aspect of the invention relates to an (expanded) radiation-emitting apparatus that comprises a first and a second (simple) radiation-emitting apparatus that are each formed as described above. In this case, the cover support of the second (simple) radiation-emitting apparatus is formed by the cover support of the first (simple) radiation-emitting apparatus, that is to say the first and the second radiation-emitting apparatuses have a common cover support. The substrate of the first (simple) radiation-emitting apparatus and the substrate of the second (simple) radiation-emitting apparatus are arranged on opposite sides of the common cover support. An apparatus is hereby provided that emits radiation on both sides and that can be easily installed in a multiplicity of possible configurations. More precisely, the substrate of the first (simple) radiation-emitting apparatus forms a first radiation exit surface and the substrate of the second (simple) radiation-emitting apparatus forms a second radiation exit surface of the (expanded) radiation-emitting apparatus.

According to at least one embodiment of the radiation-emitting apparatus, provision is made that the contact elements of the first (simple) radiation-emitting apparatus are formed by a structured metallization on a first major surface of the cover support and the contact elements of the second (simple) radiation-emitting apparatus are formed by a structured metallization on a second major surface of the cover support opposite the first major surface.

A further aspect of the invention relates to a method for producing a (simple) radiation-emitting apparatus that is formed as described above.

According to at least one embodiment, the method comprises the following method steps:
providing a substrate and a multiplicity of optoelectronic devices arranged on the substrate, wherein the optoelectronic devices are arranged in rows that extend in parallel with a preferential direction, and wherein each of the optoelectronic devices comprises a layer sequence that is suitable for generating electromagnetic radiation having at least one first electrode surface, at least one second electrode surface and at least one functional layer between the first electrode surface and the second electrode surface;
providing a cover element, wherein the cover element comprises a cover support and a multiplicity of first and second strip-like contact elements on a major surface of the cover support; and
attaching the cover element to the multiplicity of optoelectronic devices, wherein the multiplicity of first contact elements are each connected (directly or indirectly) to the first electrode surfaces of at least some of the optoelectronic devices in an electrically conductive manner, and the multiplicity of second contact elements are each connected (directly or indirectly) to the second electrode surfaces of at least some of the optoelectronic devices in an electrically conductive manner.

For example, the cover element can be adhered to the multiplicity of optoelectronic devices.

Preferably, the multiplicity of first and second contact elements of the cover element are produced by laser-structuring of a metallization on one of the major surfaces of the cover support.

A further aspect of the invention relates to a method for producing an (expanded) radiation-emitting apparatus that is formed as described above.

According to at least one embodiment, the method comprises the following method steps:
providing a first substrate and a first multiplicity of optoelectronic devices arranged on the first substrate, wherein the optoelectronic devices are arranged in rows that extend in parallel with a preferential direction, and wherein each of the optoelectronic devices comprises a layer sequence that is suitable for generating electromagnetic radiation having at least one first electrode surface, at least one second electrode surface and at least one functional layer between the first electrode surface and the second electrode surface;
providing a second substrate and a second multiplicity of optoelectronic devices arranged on the second substrate, wherein the optoelectronic devices are arranged in rows that extend in parallel with a preferential direction, and wherein each of the optoelectronic devices comprises a layer sequence that is suitable for generating electromagnetic radiation having at least one first electrode surface, at least one second electrode surface and at least one functional layer between the first electrode surface and the second electrode surface;
providing a cover element, wherein the cover element comprises a cover support and a first multiplicity of first and second strip-like contact elements on a first major surface of the cover support and a second multiplicity of first and second strip-like contact elements on a second major surface of the cover support;
attaching the cover element to the first multiplicity of optoelectronic devices, wherein the first multiplicity of first contact elements are each connected (directly or indirectly) to the first electrode surfaces of at least some of the first multiplicity of optoelectronic devices in an electrically conductive manner, and the first multiplicity of second contact elements are each connected (directly or indirectly) to the second electrode surfaces of at least some of the first multiplicity of optoelectronic devices in an electrically conductive manner; and
attaching the cover element to the second multiplicity of optoelectronic devices, wherein the second multiplicity of first contact elements are each connected (directly or indirectly) to the first electrode surfaces of at least some of the second multiplicity of optoelectronic devices in an electrically conductive manner, and the second multiplicity of second contact elements are each connected (directly or indirectly) to the second electrode surfaces of at least some of the second multiplicity of optoelectronic devices in an electrically conductive manner.

### BRIEF DESCRIPTION OF THE DRAWINGS

Further advantages, advantageous embodiments and developments are apparent from the exemplified embodiments described below in conjunction with the figures.

In the figures:

FIGS. 1 to 6 show a method for producing a radiation-emitting apparatus in accordance with the invention according to a first exemplified embodiment;

FIG. 7 shows a finished radiation-emitting apparatus in accordance with the invention according to the first exemplified embodiment;

FIGS. 8 and 9 show schematic sectional views of the radiation-emitting apparatus;

FIGS. 10-13 show a radiation-emitting apparatus and a method for producing same according to a second exemplified embodiment of the invention; and

FIG. 14 shows one possible application of the radiation-emitting apparatus 200 as an illumination device.

In the exemplified embodiments and figures, like or similar elements or elements acting in an identical manner may each be provided with the same reference numerals. The illustrated elements and their size ratios with respect to each other are not to be considered as being to scale; rather individual elements, such as, e.g., layers, components, devices and regions, can be illustrated excessively large in order to enable better illustration and/or for improved understanding; this can relate to individual dimensions or to all dimensions of the elements.

### DETAILED DESCRIPTION OF ILLUSTRATIVE EMBODIMENTS

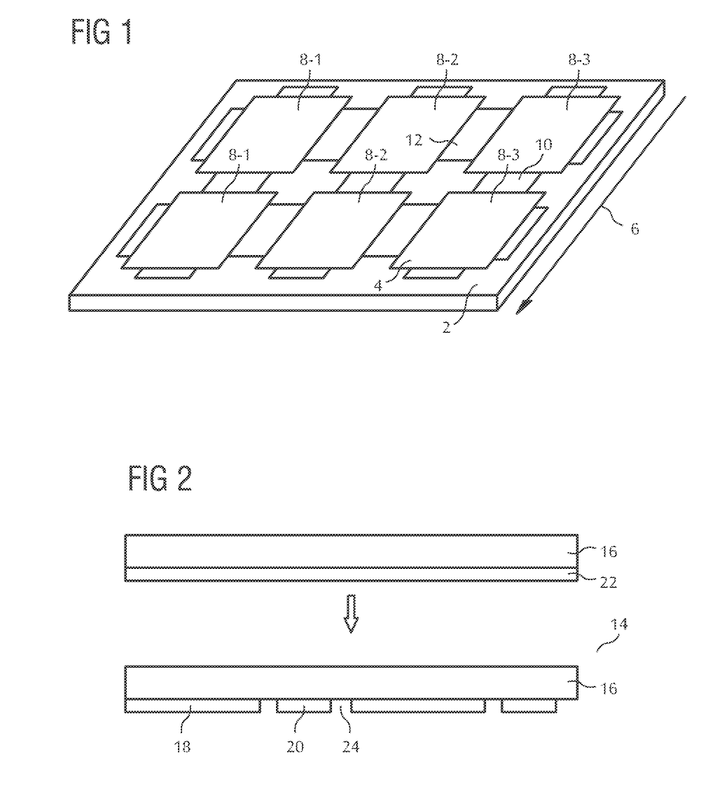

FIGS. 1 to 6 show a method for producing a radiation-emitting apparatus in accordance with the invention according to a first exemplified embodiment, said apparatus being designated as a whole by reference numeral 100.

In a first method step, a substrate 2 is provided that consists, for example, of glass and on which a multiplicity of optoelectronic devices 4 in the form of organic light-emitting diodes are arranged. The optoelectronic devices are arranged in parallel rows 8-1, 8-2, 8-3 that extend in parallel with a preferential direction 6. First contact structures 10 are arranged in regions between two optoelectronic devices 4 that lie next to each other in each case in a row 8-1, 8-2, 8-3, said contact structures connecting the cathodes, not shown in FIG. 1, of the optoelectronic devices of one row together.

Second contact structures 12 are provided in regions between two optoelectronic devices 4 lying next to each other from two adjacent rows (e.g., 8-1 and 8-2), said contact structures connecting the anodes (likewise not shown) of the adjacent optoelectronic devices 4 together.

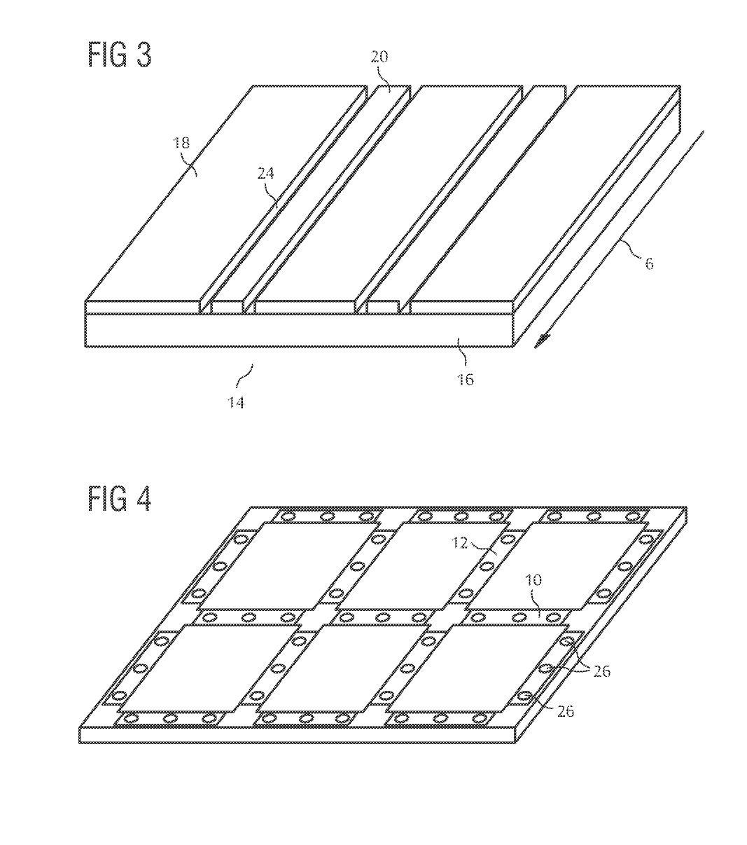

In a further method step, a cover element 14 is provided with a cover support 16 and a multiplicity of first and second strip-like contact elements 18, 20 (FIG. 2). The first and second strip-like contact elements 18, 20 are formed by laser-structuring of a metallization 22 on one of the major surfaces of the cover support 16. More precisely, the metallization 22 is partitioned by a laser along parallel lines 24, and therefore the contact strips 18, 20 arranged in an alternating manner are electrically separated from each other. The structure produced hereby is shown in plan view in FIG. 3.

In a further method step, a conductive adhesive 26 is applied to the first and second contact structures 10, 12, e.g., in small, non-contiguous regions, as shown in FIG. 4. Furthermore, an adhesive 28 is applied to the first contact elements 18 in regions that are to be attached to the individual optoelectronic devices 4, as shown in FIG. 5.

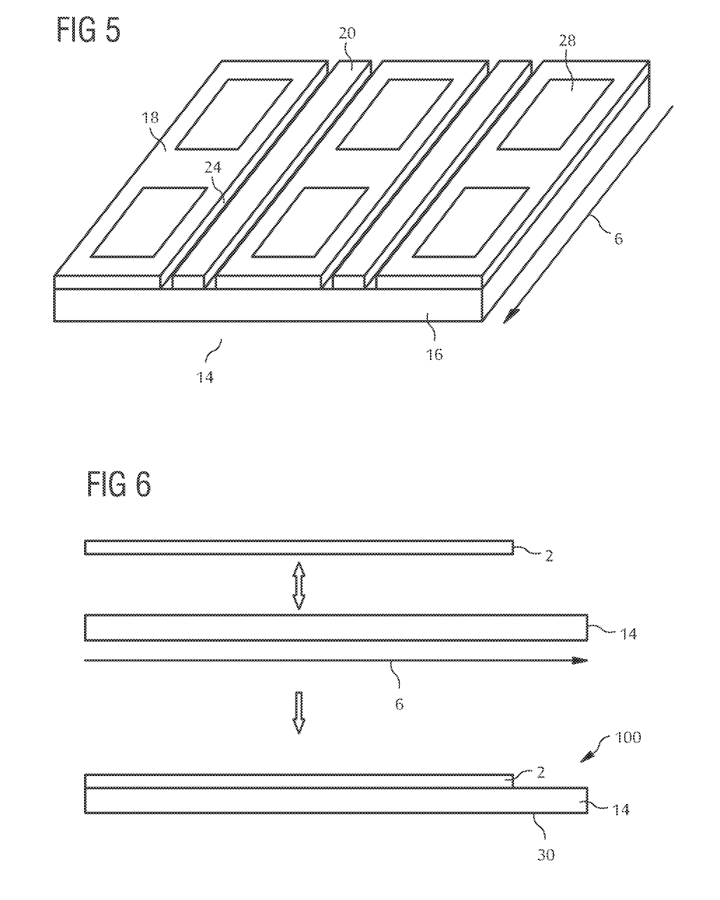

In a further method step shown in FIG. 6, the glass substrate 2 together with the optoelectronic devices 4 (not shown) arranged thereon are adhered to the cover element 14, thus producing the radiation-emitting apparatus 100 in accordance with the invention. The cover element 14 protrudes beyond the substrate 2 in the preferential direction 6 and hereby forms a contacting strip 30, by way of which the radiation-emitting apparatus 100 can be supplied with electrical energy.

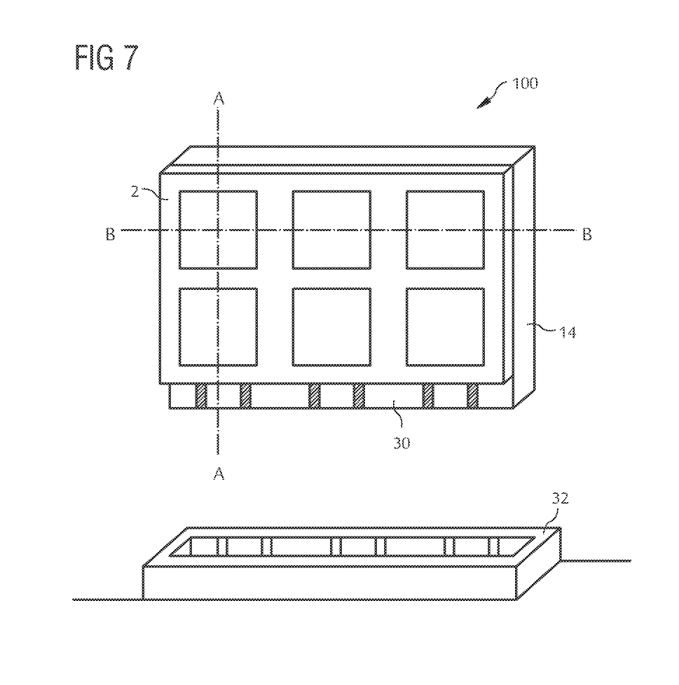

FIG. 7 shows the finished radiation-emitting apparatus 100 in accordance with the invention according to the first exemplified embodiment, wherein the contacting strip 30 of said apparatus can be inserted into a corresponding separate fitting 32. The major surface of the substrate 2 facing away from the cover element 14 forms a radiation exit surface of the apparatus 100, wherein radiation exits merely in the regions that lie opposite the optoelectronic devices 4 arranged on the substrate 2. By virtue of the fact that the cover element 14 comprises opaque contact elements, light is emitted only on one side of the radiation-emitting apparatus 100.

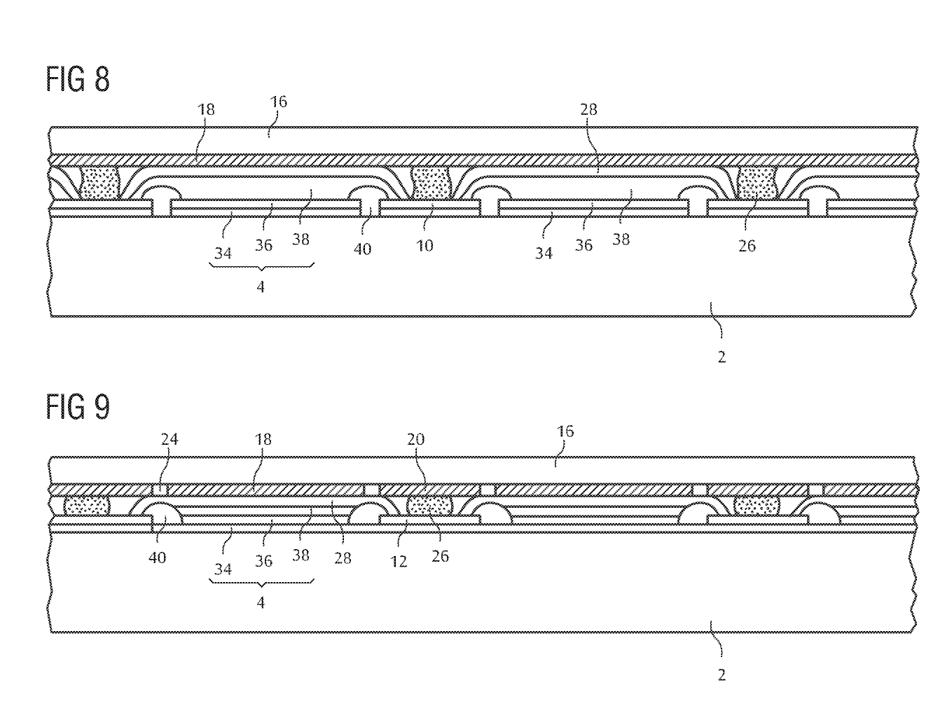

FIGS. 8 and 9 show schematic sectional views of the radiation-emitting apparatus 100, wherein the section in FIG. 8 is taken along line A-A in FIG. 7 and the section in FIG. 9 is taken along line B-B in FIG. 7. As shown in FIG. 8, each of the optoelectronic devices 4 comprises a transparent anode 34, a cathode 38 and an organic functional layer 36 arranged therebetween. The section shown in FIG. 8 extends through one of the rows 8-1, 8-2, 8-3 shown in FIG. 1. The cathodes 38 of two adjacent optoelectronic devices 4 are connected together via the first contact structures 10. These are connected to the first contact element 18 in a conductive manner via the conductive adhesive 26. By way of this arrangement, the first contact element 18 is at least indirectly connected to the cathodes 38 of the optoelectronic devices of one row. The optoelectronic devices 4 are separated from each other by insulating resistance elements 40.

FIG. 9 shows a section perpendicular to the preferential direction 6 in FIG. 1 and thus over adjacent rows 8-1, 8-2 and 8-3 (see, FIG. 1). The optoelectronic devices 4 are also separated from each other in this section by insulating resistance elements 40. In this sectional view, the transparent anode 34 extends in an uninterrupted manner on the substrate 2 and is connected to the second contact structures 12 in a conductive manner in regions between adjacent optoelectronic devices 4, said contact structures in turn being connected to the second contact elements 20 in an electrically conductive manner via the conductive adhesive 26. Therefore, the anodes of the optoelectronic devices are connected at least indirectly to the second contact elements in an electrically conductive manner.

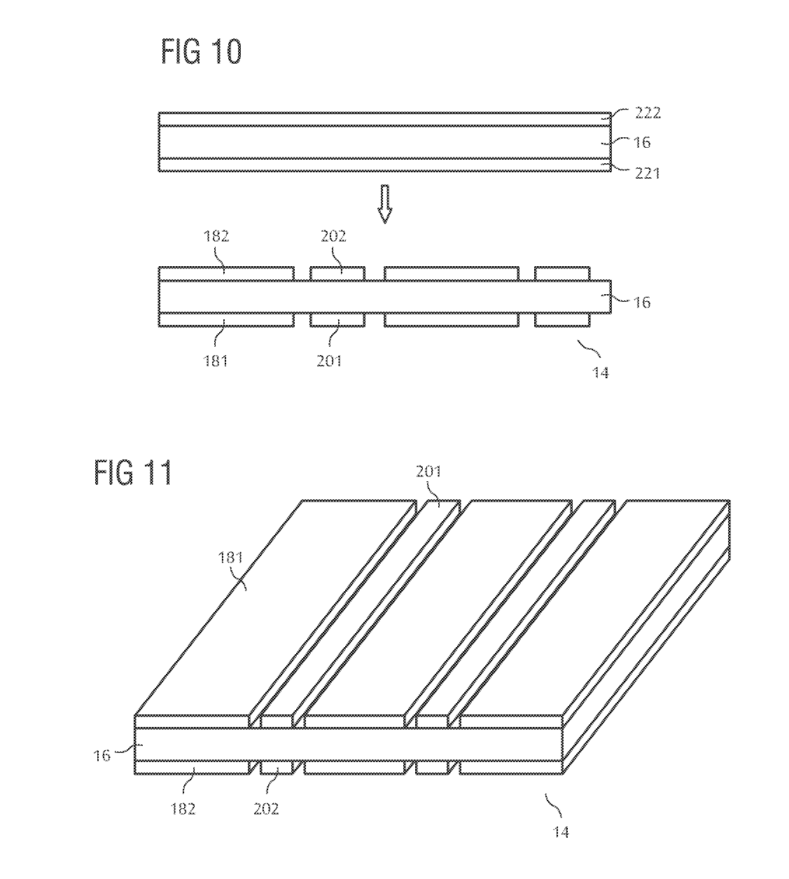

FIGS. 10-13 show a radiation-emitting apparatus and a method for producing same according to a further exemplified embodiment of the invention.

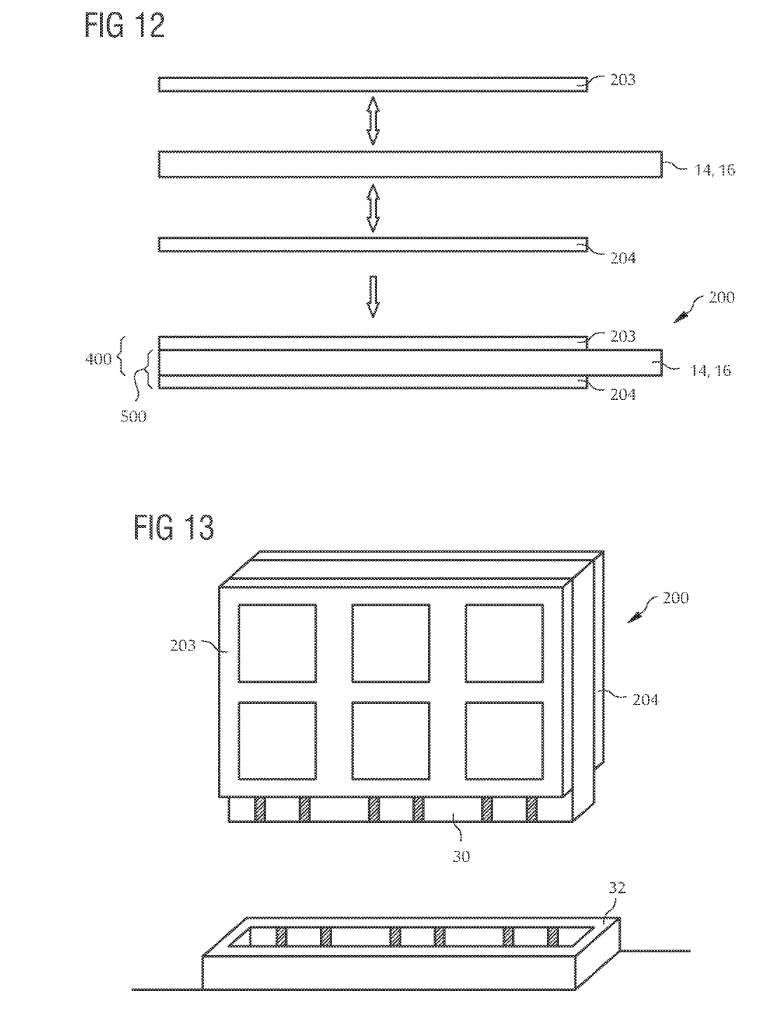

In contrast to the first exemplified embodiment, a metallization 221, 222 is provided on each of the two major surfaces of the cover support 16 during production. Thereupon, both sides of the cover support 16 are structured such that a first multiplicity of first and second contact elements 181, 201 are provided and a second multiplicity of first and second contact elements 182, 202 are provided on the opposite side of the cover support 16. Now, a first substrate 203 having optoelectronic devices (not shown) arranged thereon and a second substrate 204 having optoelectronic devices (not shown) arranged thereon are adhered on both sides to the cover element 14 that is provided with contact elements on both sides, as shown in FIG. 12.

The arrangement of the optoelectronic devices on the first substrate 203 and the second substrate 204 corresponds to the above-described corresponding arrangement according to the first exemplified embodiment. A sandwich structure is produced in which two layers of optoelectronic devices, arranged in rows, are arranged between the cover element 14 on the one hand and each one of the substrates 203, 204 on the other hand. In this manner, an (expanded) apparatus 200 emitting radiation on both sides is provided that comprises a first (simple) radiation-emitting apparatus 400 according to the first exemplified embodiment and a second (simple) radiation-emitting apparatus 500 according to the first exemplified embodiment, wherein the cover support 16 of the second radiation-emitting apparatus 500 is formed by the cover support of the first radiation-emitting apparatus 400. In a similar manner to the first exemplified embodiment, it can be supplied with electrical energy by a contacting strip 30, as shown in FIG. 13.

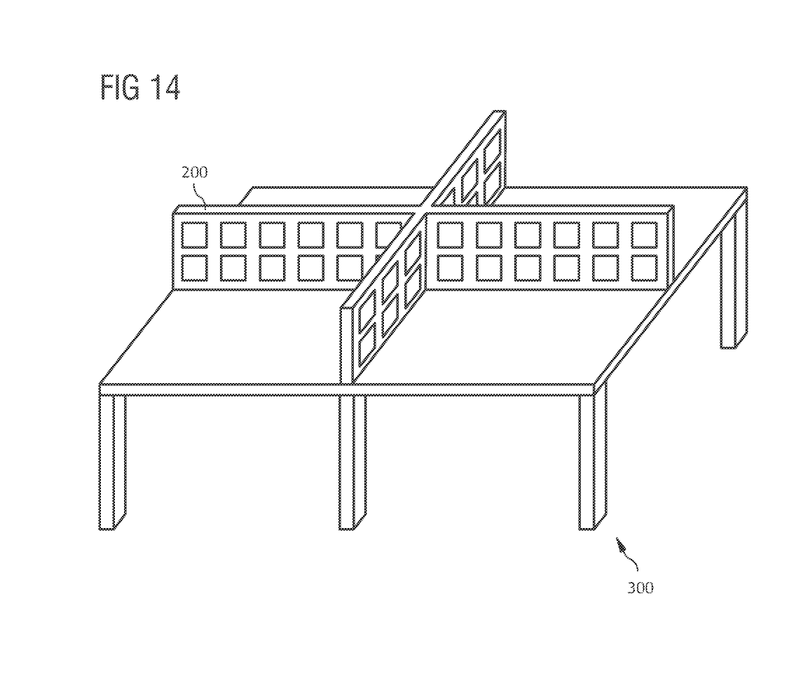

FIG. 14 shows one possible application of the radiation-emitting apparatus 200 as an illumination device on a table 300. In this case, a multiplicity of radiation-emitting apparatuses 200 are positioned on a tabletop in different orientations, said tabletop being illuminated uniformly by the apparatuses.

1-13. (canceled)

14. A radiation-emitting apparatus, comprising:
a substrate;
a plurality of optoelectronic devices arranged on the substrate in rows that extend in parallel with a preferential direction, wherein each of the optoelectronic devices comprises a layer sequence having a first electrode surface, a second electrode surface and a functional layer between the first electrode surface and the second electrode surface, wherein the functional layer is suitable for generating electromagnetic radiation in a switched-on operating state; and
a cover element arranged over the plurality of optoelectronic devices, the cover element comprising a plurality of first contact elements, each one connected to the first electrode surfaces of at least some of the optoelectronic devices in an electrically conductive manner and a plurality of second contact elements, each one connected to second electrode surfaces of at least some of the optoelectronic devices in an electrically conductive manner, wherein the first and second contact elements are formed in a strip-like manner and extend along the preferential direction.

15. The radiation-emitting apparatus according to claim 14, wherein the substrate is transparent.

16. The radiation-emitting apparatus according to claim 14, wherein each of the first contact elements is arranged over one of the rows of optoelectronic devices.

17. The radiation-emitting apparatus according to claim 14, wherein each of the second contact elements is arranged over a region between two adjacent rows of optoelectronic devices.

18. The radiation-emitting apparatus according to claim 14, wherein each of the first contact elements is connected to first contact structures that are formed in regions between two optoelectronic devices lying next to each other in a row.

19. The radiation-emitting apparatus according to claim 14, wherein each of the second contact elements is connected to second contact structures that are formed in regions between two optoelectronic devices lying next to each other from two adjacent rows.

20. The radiation-emitting apparatus according to claim 14, wherein ones of the first and second contact elements are attached to contact structures of the optoelectronic devices via a conductive adhesive.

21. The radiation-emitting apparatus according to claim 14, wherein the first and second contact elements are formed by a structured metallization on a major surface of the cover element.

22. The radiation-emitting apparatus according to claim 21, wherein the structured metallization is on a cover support of the cover element.

23. The radiation-emitting apparatus according to claim 14, wherein the cover element protrudes beyond the substrate in the preferential direction.

24. A radiation-emitting apparatus comprising:
a first substrate;
a first plurality of optoelectronic devices arranged on the first substrate in rows that extend in parallel with a preferential direction, wherein each of the optoelectronic devices of the first plurality comprises a layer sequence having a first electrode surface, a second electrode surface and a functional layer between the first electrode surface and the second electrode surface, wherein the functional layer is suitable for generating electromagnetic radiation in a switched-on operating state;
a second substrate;
a second plurality of optoelectronic devices arranged on the second substrate in rows that extend in parallel with the preferential direction, wherein each of the optoelectronic devices of the second plurality comprises a layer sequence having a first electrode surface, a second electrode surface and a functional layer between the first electrode surface and the second electrode surface, wherein the functional layer is suitable for generating electromagnetic radiation in a switched-on operating state; and
a cover element having a first major surface arranged over the first plurality of optoelectronic devices and a second major surface arranged over the second plurality of optoelectronic devices, the second major surface opposite the first major surface;
wherein the first major surface of the cover element comprises a plurality of first contact elements, each one electrically connected to the first electrode surfaces of some of the optoelectronic devices of the first plurality and also comprises a plurality of second contact elements, each one electrically connected to second electrode surfaces of some of the optoelectronic devices of the first plurality, wherein the first and second contact elements of the first major surface are formed in a strip-like manner and extend along the preferential direction; and
wherein the second major surface of the cover element comprises a plurality of first contact elements, each one electrically connected to the first electrode surfaces of some of the optoelectronic devices of the second plurality and also comprises a plurality of second contact elements, each one electrically connected to second electrode surfaces of some of the optoelectronic devices of the second plurality, wherein the first and second contact elements of the second major surface are formed in a strip-like manner and extend along the preferential direction.

25. The radiation-emitting apparatus according to claim 24, wherein the first and second contact elements on the first major surface of the cover element are formed by structured metallization and wherein the first and second contact elements on the second major surface of the cover element are formed by structured metallization.

26. A method for producing the radiation-emitting apparatus according to claim 24, the method comprising:
providing the first substrate with the first plurality of optoelectronic devices arranged on the first substrate;
providing the second substrate with the second plurality of optoelectronic devices arranged on the second substrate;
providing the cover element, wherein the cover element comprises a cover support with the plurality of first and second contact elements on a first major surface of the cover support and the plurality of first and second contact elements on a second major surface of the cover support;
attaching the cover element to the first plurality of optoelectronic devices; and
attaching the cover element to the second plurality of optoelectronic devices.

27. The method according to claim 26, wherein the first and second contact elements on the first major surface of the cover element are formed by structured metallization and wherein the first and second contact elements on the second major surface of the cover element are formed by structured metallization.

28. A method for producing a radiation-emitting apparatus, the method comprising:
providing a plurality of optoelectronic devices arranged on a substrate, wherein the optoelectronic devices are arranged in rows that extend in parallel with a preferential direction, and wherein each of the optoelectronic devices comprises a layer sequence that is suitable for generating electromagnetic radiation, the layer sequence having a first electrode surface, a second electrode surface and a functional layer between the first electrode surface and the second electrode surface;
providing a cover element, wherein the cover element comprises a cover support and a plurality of first strip-like contact elements and a plurality of second strip-like contact elements on a major surface of the cover support; and
attaching the cover element to the plurality of optoelectronic devices, wherein the plurality of first contact elements are each connected to the first electrode surfaces of at least some of the optoelectronic devices in an electrically conductive manner, and the plurality of second contact elements are each connected to the second electrode surfaces of at least some of the optoelectronic devices in an electrically conductive manner.

29. The method according to claim 28, wherein the substrate is transparent.

30. The method according to claim 28, wherein each of the first contact elements is arranged over one of the rows of optoelectronic devices and wherein each of the second contact elements is arranged over a region between two adjacent rows of optoelectronic devices.

31. The method according to claim 28, wherein each of the first contact elements is connected to first contact structures that are formed in regions between two optoelectronic devices lying next to each other in a row and wherein each of the second contact elements is connected to second contact structures that are formed in regions between two optoelectronic devices lying next to each other from two adjacent rows.
